(19) United States
(12) Patent Application Publication
(10) Pub. No.: US 2025/0185308 A1
(43) Pub. Date: Jun. 5, 2025

(54) SEMICONDUCTOR DEVICE AND ELECTRONIC DEVICE INCLUDING THE SAME

(71) Applicant: Samsung Electronics Co., Ltd., Suwon-si (KR)

(72) Inventors: Donghoon KIM, Suwon-si (KR); Seunggeol NAM, Suwon-si (KR); Sijung YOO, Suwon-si (KR); Hyunjae LEE, Suwon-si (KR)

(73) Assignee: Samsung Electronics Co., Ltd., Suwon-si (KR)

(21) Appl. No.: 18/961,672

(22) Filed: Nov. 27, 2024

(30) Foreign Application Priority Data
Dec. 5, 2023 (KR) 10-2023-0174832

(51) Int. Cl. H10D 30/69; H10B 51/30

(52) U.S. Cl. CPC H10D 30/69; H10B 51/30; H10D 30/701

(57) ABSTRACT

A semiconductor device includes a channel layer comprising a semiconductor material, a ferroelectric layer disposed on the channel layer and comprising a ferroelectric material, a gate electrode disposed on the ferroelectric layer, a first insulating layer disposed between the ferroelectric layer and the gate electrode, a charge trap layer disposed between the ferroelectric layer and the first insulating layer and comprising a matrix material and a plurality of nano-crystals embedded in the matrix material, and a second insulating layer disposed between the channel layer and the ferroelectric layer. A center of an overall arrangement of the plurality of nano-crystals is located in an area closer to the ferroelectric layer than a first insulating layer in an area of the charge trap layer.

### CROSS-REFERENCE TO RELATED APPLICATION

This application claims the benefit of Korean Patent Application No. 10-2023-0174832, filed on Dec. 5, 2023, in the Korean Intellectual Property Office, the disclosure of which is incorporated herein in its entirety by reference.

### BACKGROUND

### 1. Field

The disclosure relates to a semiconductor device and an electronic device including the same.

### 2. Description of the Related Art

Ferroelectrics are materials with ferroelectricity that maintain spontaneous polarization by aligning internal dipole moments even when no electric field is applied thereto from the outside. Even if a certain voltage is applied to ferroelectrics and the voltage is brought back to 0 V, the polarization in the ferroelectrics remains semi-permanently (e.g., the polarization is maintained even after the applied voltage is stopped). Researches have been continued to apply such ferroelectric characteristics to logic devices or memory devices. For example, in the case of a ferroelectric field effect transistor including a ferroelectric, the threshold voltage of the ferroelectric field effect transistor may vary with the polarization direction within the ferroelectric. A logic device and/or a memory device may be implemented by using the threshold voltage change characteristics of the ferroelectric field effect transistor.

### SUMMARY

Provided are a semiconductor device and an electronic device including the same.

Additional aspects will be set forth in part in the description which follows and, in part, will be apparent from the description, or may be learned by practice of the presented embodiments.

According to an aspect of the disclosure, a semiconductor device includes a channel layer comprising a semiconductor material; a gate electrode on the channel layer; a ferroelectric layer between the channel layer and the gate electrode, the ferroelectric layer comprising a ferroelectric material; a first insulating layer between the ferroelectric layer and the gate electrode; a charge trap layer between the ferroelectric layer and the first insulating layer, the charge trap layer comprising a matrix material and a plurality of nano-crystals embedded in the matrix material; and a second insulating layer between the channel layer and the ferroelectric layer, wherein, in the charge trap layer, a center of an overall arrangement of the plurality of nano-crystals is in an area closer to the ferroelectric layer than to the first insulating layer

The plurality of nano-crystals may include an element included in the matrix material.

The center of the overall arrangement of the plurality of nano-crystals may be at a distance of 2 nm or less from an interface between the ferroelectric layer and the charge trap layer.

At least a majority of the plurality of nano-crystals may be located within 70% or less of the thickness of the charge trap layer from an interface between the ferroelectric layer and the charge trap layer.

At least two of the plurality of nano-crystals may be spaced apart from each other.

The plurality of nano-crystals may be arranged such that the plurality of nano-crystals are not entirely connected to each other and do not form a layer.

The volume ratio of the plurality of nano-crystals in an area at a first distance from the first surface is 50% or less, and the first distance is a distance between one end of a nano-crystal, of the plurality of nano-crystals, located farthest from an interface between the ferroelectric layer and the charge trap layer and the interface.

The charge trap layer may include at least one of AlN, GaN, GeN, SiN, CN, InN, YN, ScN, or ZrN.

The matrix material may include SiN, and the plurality of nano-crystals may include Si.

The matrix material may include GeN, and the plurality of nano-crystals may include Ge.

The second insulating layer may include an oxide of a material included in the channel layer.

A ferroelectric material included in the ferroelectric layer may include a hafnium oxide-based material.

The hafnium oxide-based material may include at least one of Zr, La, Al, Si, Y, B, or Sc as a dopant.

The channel layer may include at least one of Si, Ge, SiGe, MoS₂, WSe₂, graphene, IGZO, IWO, or ZnSnO.

According to another aspect of the disclosure, an electronic device includes a semiconductor substrate; and a plurality of memory cells stacked on the semiconductor substrate,

wherein each of the plurality of memory cells comprises a channel layer comprising a semiconductor material, a plurality of gate electrodes spaced apart from each other in a first direction, a ferroelectric layer between the channel layer and the plurality of gate electrodes, the ferroelectric layer comprising a ferroelectric material, a first insulating layer between the ferroelectric layer and the plurality of gate electrodes, a charge trap layer between the ferroelectric layer and the first insulating layer, the charge trap layer comprising a matrix material and a plurality of nano-crystals embedded in the matrix material, and a second insulating layer disposed between the channel layer and the ferroelectric layer, wherein, the charge trap layer, a center of an overall arrangement of the plurality of nano-crystals is in an area closer to the ferroelectric layer than to the first insulating layer, and wherein the first direction is perpendicular to a stack direction of the plurality of memory cells.

The plurality of nano-crystals may include an element included in the matrix material.

The center of the overall arrangement of the plurality of nano-crystals may be at a distance of 2 nm or less from an interface between the ferroelectric layer and the charge trap layer.

A plurality of spacers including an insulating material may be disposed between the plurality of gate electrodes adjacent to each other.

The plurality of gate electrodes and the spacer may have a cylinder shell shape with connected inner surfaces.

According to another aspect of the disclosure, an electronic device an array comprising a plurality of synapse devices that are two-dimensionally arranged, wherein each of the plurality of synapse devices comprises an access transistor and a ferroelectric field effect transistor, wherein the ferroelectric field effect transistor comprises a channel layer comprising a semiconductor material, a plurality of gate electrodes spaced apart from each other in a first direction, a ferroelectric layer between the channel layer and the plurality of gate electrodes, the ferroelectric layer comprising a ferroelectric material, a first insulating layer between the ferroelectric layer and the plurality of gate electrodes, a charge trap layer between the ferroelectric layer and the first insulating layer, the charge trap layer comprising a matrix material and a plurality of nano-crystals embedded in the matrix material, and a second insulating layer between the channel layer and the ferroelectric layer, and wherein, in the charge trap layer, a center of an overall arrangement of the plurality of nano-crystals is in an area closer to the ferroelectric layer than to the first insulating layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a schematic structure of a semiconductor device according to at least one embodiment;

FIG. 2 is a detailed cross-sectional view of a charge trap layer provided in the semiconductor device of FIG. 1;

FIG. 3 is a graph showing a concept of a memory window indicated by a semiconductor device according to at least one embodiment;

FIG. 4A is a conceptual view illustrating an electric charge distribution in a semiconductor device according to at least one embodiment when the semiconductor device is in a program state;

FIG. 4B illustrates an example of an electric charge density in a semiconductor device according to at least one embodiment when the semiconductor device is in the program state;

FIG. 5A is a conceptual view illustrating an electric charge distribution in a semiconductor device according to at least one embodiment when the semiconductor device is in an erase state;

FIG. 5B illustrates an example of an electric charge density in a semiconductor device according to at least one embodiment when the semiconductor device is in the erase state;

FIG. 6 is a cross-sectional view of a schematic structure of a semiconductor device according to a comparative example;

FIGS. 7A and 7B illustrate examples of an electric charge density in a semiconductor device according to a comparative example when the semiconductor device is in a program state and an erase state;

FIG. 8A is a cross-sectional view showing a schematic structure of a memory device according to at least one embodiment, and FIG. 8B is a cross-sectional view of the memory device of FIG. 8A taken along line A-A′;

FIG. 9 is an equivalent circuit of a memory device according to at least one embodiment;

FIG. 10 is a schematic circuit diagram of a neural network device according to at least one embodiment; and

FIG. 11 is a schematic block diagram of an electronic device including a neural network device according to at least one embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects.

Hereinafter, embodiments are described in detail with reference to the accompanying drawings. Embodiments described below are just examples, and various modifications are available from the embodiments. Throughout the drawings, like reference numerals denote like elements, and sizes of components in the drawings may be exaggerated for convenience of explanation and clarity.

Hereinbelow, when a constituent element is disposed “above” or “on” to another constituent element, the constituent element may be only directly on the other constituent element or above the other constituent elements in a non-contact manner. Additionally, it will be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

It will be understood that although the terms “first,” “second,” etc. may be used herein to describe various components, these components should not be limited by these terms. These terms are only used to distinguish one component from another. These terms do not limit that the materials or structures of components are different from each other.

As used herein, the singular forms “a,” “an,” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

Furthermore, terms such as “ . . . portion,” “ . . . unit,” “ . . . module,” and “ . . . block” stated in the specification may signify a unit to process at least one function or operation and the unit may be embodied and/or implemented by processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

The use of the terms “a,” “an,” “the,” and similar referents in the context of describing the disclosure are to be construed to cover both the singular and the plural.

The operations of all methods described herein can be performed in any suitable order unless otherwise indicated herein or otherwise clearly contradicted by context. Furthermore, the use of any and all examples, or language (e.g., “such as”) provided herein, is intended merely to better illuminate the disclosure and does not pose a limitation on the scope of the disclosure unless otherwise claimed.

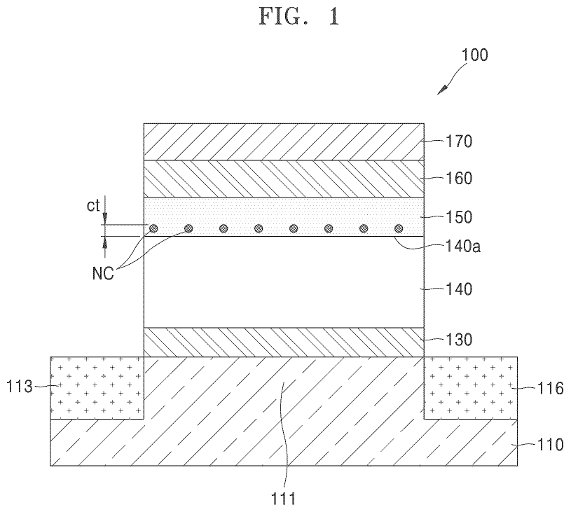

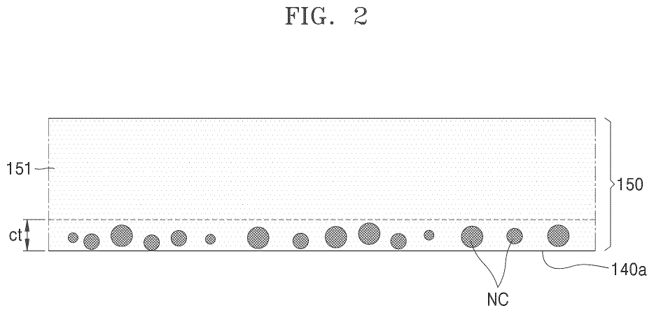

FIG. 1 is a cross-sectional view of a schematic structure of a semiconductor device 100 according to at least one embodiment, and FIG. 2 is a detailed cross-sectional view of a charge trap layer provided in the semiconductor device 100 of FIG. 1.

The semiconductor device 100 may include a channel layer 111 including a semiconductor material, a ferroelectric layer 140 disposed above the channel layer 111 and including a ferroelectric material, a gate electrode 170 disposed above the ferroelectric layer 140 and including a conductive material, a first insulating layer 160 disposed between the ferroelectric layer 140 and the gate electrode 170 and including an insulating material, a charge trap layer 150 disposed between the ferroelectric layer 140 and the first insulating layer 160, and a second insulating layer 130 disposed between the channel layer 111 and the ferroelectric layer 140 and including an insulating material.

The charge trap layer 150 may include a plurality of nano-crystals NC for memory window expansion. The charge trap layer 150 may include, for example, a material that can implement a charge trap that is lower than the conduction band of a material by 1 eV or more. In at least one embodiment, the charge trap layer 150 may include various types of nitrides. The charge trap layer 150 may include, for example, at least one of AlN, GaN, GeN, SiN, CN, InN, YN, ScN, and/or ZrN.

The thickness of the charge trap layer 150 may be 10 nm or less, 7 nm or less, and/or 5 nm or less.

As described in detail in FIG. 2, the charge trap layer 150 may include a matrix material 151, and the nano-crystals NC embedded in the matrix material 151. The matrix material 151 may include the nitride (e.g., one or more selected from among AlN, GaN, GeN, SiN, CN, InN, YN, ScN, and/or ZrN). The nano-crystals NC may include one or more selected from among aluminum (Al), gallium (Ga), germanium (Ge), silicon (Si), carbon (C), indium (In), yttrium (Y), scandium (Sc), and zirconium (Zr). The nano-crystals NC may further include at least one element included in the compound forming the matrix material 151. For example, when the matrix material 151 includes SiN, the nano-crystals NC may include crystalline Si, and/or when the matrix material 151 includes GeN, the nano-crystals NC may include crystalline Ge.

The nano-crystals NC may be most disposed adjacent to the ferroelectric layer 140. The center of the overall arrangement of the nano-crystals NC may be positioned in the area of the charge trap layer 150 and closer to the ferroelectric layer 140 than the first insulating layer 160. In the charge trap layer 150, a location where the arrangement density of the nano-crystals NC is the greatest may be closer to the ferroelectric layer 140 than the first insulating layer 160, in the area of the charge trap layer 150. The nano-crystals NC may be located, as a whole, in an area closer to the ferroelectric layer 140 than the first insulating layer 160, in the area of the charge trap layer 150.

Most or almost all of the nano-crystals NC may be located within an area at a certain distance, for example, a distance ct, from a first surface 140a that is an interface between the ferroelectric layer 140 and the charge trap layer 150. The distance ct may be, for example, 3 nm or less, 2.5 nm or less, 2 nm or less, 1.5 nm or less, or 1 nm or less. For example, the distance ct may be 70% or less, 60% or less, 50% or less, or 40% or less of the thickness of the charge trap layer 150.

In the above description, the expressions of “all,” “most,” and “almost all” of the nano-crystals NC mean about 100% of the nanocrystals NC, but these expressions are not strictly limited to 100% numerically and may mean, for example, 90% or more, 95% or more, 97% or more, or 99% or more.

Although FIG. 1 illustrates that all the nano-crystals NC have the same size and have the same relative positions with respect to the ferroelectric layer 140 within the charge trap layer 150, this is an illustrated for convenience of explanation. As illustrated in FIG. 2, the nano-crystals NC may have various sizes, and the shape of each nano-crystal NC is not limited to a ball shape. The diameters of the nano-crystals NC may include, for example, 3 nm or less, 2 nm or less, 1.5 nm or less, 1 nm or less, and/or 0.7 nm or less. The distance from the first surface 140a to each of the nano-crystals NC may vary. The distance may be, for example, 0 nm to 2 nm.

The nano-crystals NC may be spaced apart from each other. For example, at least two of the nano-crystals NC may be spaced apart from each other. In other words, although the nano-crystals NC are arranged to be adjacent to each other, the nano-crystals NC are spaced apart from each other not to form a layer.

When a distance from one end of one of the nano-crystals NC located at a distance farthest from the first surface 140a that is an interface between the ferroelectric layer 140 and the charge trap layer 150, among the nano-crystals NC, to the first surface 140a is ct, a volume ratio of the nano-crystals NC in a region within a distance ct from the first surface 140a may be a certain value or less. The upper limit of the volume ratio may be proposed not to include a shape in which the nano-crystals NC are all arranged in contact with each other to form a layer. For example, in the charge trap layer 150 according to at least one embodiment, a space occupancy rate (e.g., a volume ratio) of the nano-crystals NC being arranged in a space in which a distance ct from the first surface 140a may be 52.4% or less, 50% or less, 45% or less, or 40% or less and 3% or more, 5% or more, 10% or more, or 15% or more.

The charge trap layer 150 may be formed by controlling conditions, such as a deposition speed, a deposition temperature, and/or the like, in a deposition process of forming the matrix material 151, for example, an atomic layer deposition (ALD) process or a plasma enhanced chemical vapor deposition (PECVD) process. For example, in a deposition process of forming SiN, Si nano-crystals may be formed together with SiN and in a deposition process of forming GeN, Ge nanocrystals may be formed together with GeN. The location, distribution, and/or the like of the nano-crystals NC may be controlled by deposition conditions.

As such, as the nano-crystals NC arranged adjacent to the ferroelectric layer 140 in the charge trap layer 150 form a deep trap site with the matrix material 151 forming the charge trap layer 150, electric charges captured therein do not escape well, thereby contributing to memory window expansion.

Other components of the semiconductor device 100 are described in detail as follows.

The semiconductor device 100 may include a field effect transistor indicating a different threshold voltage according to a voltage applied to the gate electrode 170.

The channel layer 111 may include a semiconductor material. The channel layer 111 may be defined as an area between a source region 113 and a drain region 116 that are spaced apart from each other in a substrate 110 including a semiconductor material and/or as an area between the source region 113 and the drain region 116 on the substrate 110 on which the source region 113 and the drain region 116 are formed.

The source region 113 and the drain region 116 may be doped as first conductive type, and the substrate 110 may be doped as second conductive type electrically opposite to the first conductive type. For example, the substrate 110 may include a p-type semiconductor and the source region 113 and the drain region 116 may include an n-type semiconductor, or the substrate 110 may include an n-type semiconductor and the source region 113 and the drain region 116 may include a p-type semiconductor. The substrate 110 may be doped at relatively low concentration of about 10¹⁶/cm³ to 10¹⁷/cm³, whereas the source region 113 and the drain region 116 may be doped at a relatively high concentration of about 10¹⁹/cm³ to 10²¹/cm³ for low resistance. The source region 113 and the drain region 116 may be formed by respectively doping the opposite sides of an upper portion of the substrate 110. An upper area of the substrate 110 where the source region 113 and the drain region 116 are not formed may become the channel layer 111.

The channel layer 111 may include an elemental (e.g., group IV) semiconductor, a two-dimensional semiconductor, a compound semiconductor, and/or an oxide semiconductor. The channel layer 111 may include, for example, Si, Ge, SiGe, MoS₂, WSe₂, graphene, indium gallium zinc oxide (IGZO), tungsten doped indium oxide (IWO), and/or ZnSnO. In addition, the channel layer 111 may include a group III-V compound semiconductor, a group II-VI compound semiconductor, and/or the like. Additionally, in at least some embodiments, the channel layer 111 may be (and/or include) a semiconductor material deposited on the substrate 110.

The substrate 110, the source region 113, and the drain region 116 may include the same based material described above with respect to the channel layer 111.

When the substrate 110, the channel layer 111, the source region 113, and the drain region 116 include Si, Ge, or SiGe, and/or the like, the substrate 110 and the channel layer 111 may each be doped with a dopant of at least one of boron (B), Al, Ga, and In, and the source region 113 and the drain region 116 may each be doped with a dopant of at least one of phosphorus (P), arsenic (As), and antimony (Sb). In these cases, the semiconductor device 100 may be referred to as an n-channel metal oxide semiconductor field effect transistor (NMOS). Alternatively, reversely, the substrate 110 and the channel layer 111 may each be doped with a dopant of at least one of P, As, and Sb, and the source region 113 and the drain region 116 may each be doped with a dopant of at least one of B, Al, Ga, and In. In these cases, the semiconductor device 100 may be referred to as a p-channel metal oxide semiconductor field effect transistor (PMOS).

The ferroelectric layer 140 may include a ferroelectric material. A ferroelectric material is a material having ferroelectricity in which spontaneous polarization is maintained as internal dipole moments are aligned even without maintaining an externally applied electric field thereto. A threshold voltage of the semiconductor device 100 may vary according as the polarization direction of the ferroelectric layer 140 is, for example, a direction from the gate electrode 170 to the channel layer 111 or reversely a direction from the channel layer 111 to the gate electrode 170.

In at least some embodiments, the ferroelectric material included in the ferroelectric layer 140 may include a hafnium oxide material and/or an aluminum nitride material. The ferroelectric material may have a structure in which a dopant is inserted in a hafnium oxide-based material or a structure in which a dopant is inserted in an aluminum nitride-based material. When a ferroelectric material included in the ferroelectric layer 140 is a hafnium oxide-based material, a dopant may include Zr, lanthanum (La), Al, Si, or Y. When a ferroelectric material included in the ferroelectric layer 140 is an aluminum nitride-based material, the dopant may include, e.g., B or Sc. The ferroelectric layer 140 may include an orthorhombic crystalline phase and/or a tetragonal crystalline phase. In some cases, the ferroelectric layer 140 may include the orthorhombic crystalline phase more than the tetragonal crystalline phase. The crystalline phase distribution may be confirmed by, for example, transmission electron microscopy (TEM), grazing incidence X-ray diffraction (GIXRD), and/or the like.

In addition, the ferroelectric layer 140 may include, for example, a ferroelectric material having at least one of a fluorite structure, a perovskite structure, and a wurtzite structure. A ferroelectric material having a fluorite structure may include, for example, a hafnium oxide HfO₂. A hafnium oxide may be doped with at least one element of, for example, Zr, La, Al, Si, Y, gadolinium (Gd), and/or the like. The ferroelectric layer 140 may also include a semi-ferroelectric material. For example, the semi-ferroelectric material may include a zirconium oxide. The zirconium oxide may be doped with at least one element of, for example, hafnium (Hf), La, Al, Si, Y, and Gd. A ferroelectric material having a perovskite structure may include, for example, lead zirconate titanate (PZT). A ferroelectric material having a wurtzite structure may include, for example, a zinc oxide (ZnO) or an aluminum nitride (AlN). The ferroelectric material having a wurtzite structure may be doped with at least one element of, for example, B and Sc. Furthermore, the ferroelectric layer 140 may include not only the ferroelectric material described above, but also a semi-ferroelectric material. For example, the ferroelectric layer 140 may include ZrO₂.

In at least some embodiments, the ferroelectric layer 140 may include at least one of Hf and Zr. The ferroelectric layer 140 may include Hf and Zr at the same (and/or substantially similar) ratio (e.g., Hf_{0.5}Zr_{0.5}O₂), and additionally, may be doped with at least one element of La, Al, Si, Y, and/or Gd at a ratio of less than 10 at %.

The thickness of the ferroelectric layer 140 may be, for example, within an inclusive range of about 5 nm to about 20 nm. However, the disclosure is not limited thereto.

The gate electrode 170 may have conductivity of about 1 Mohm/square or less. The gate electrode 170 may include one or more conductive materials selected from, e.g., the group consisting of metal, metal nitride, metal carbide, polysilicon, and/or a combination thereof. For example, the metal may include Al, tungsten (W), molybdenum (Mo), titanium (Ti), or tantalum (Ta), a metal nitride film may include a titanium nitride film (TiN film) or a tantalum nitride film (TaN film), and the metal carbide may include aluminum- or silicon-doped (or contained) metal carbide and as a detailed example, may include TiAlC, TaAlC, TiSiC, or TaSiC. The gate electrode 170 may have a stacked structure of a plurality of materials. For example, the gate electrode 170 may have a stack structure of a metal nitride layer/a metal layer, such as TiN/Al and/or the like, or a stack structure of a metal nitride layer/a metal carbide layer/a metal layer, such as TiN/TiAlC/W. The gate electrode 170 may include a titanium nitride (TiN) film or Mo, and the example presented above may be used in variously modified forms. Furthermore, the gate electrode 170 may include a conductive two-dimensional material in addition to the material described above. For example, the conductive two-dimensional material may include at least one of graphene, black phosphorus, amorphous boron nitride, two-dimensional hexagonal nitride boron (h-BN), and phosphorene.

The first insulating layer 160 disposed between the charge trap layer 150 and the gate electrode 170 may include one or more insulating materials. The first insulating layer 160 may include, for example, SiO₂, Al₂O₃, MgO₂, or AlN. When a sufficiently high voltage (e.g., a write voltage or an erase voltage) is applied to the gate electrode 170, the first insulating layer 160 may transmit electric charges from the gate electrode 170 to the charge trap layer 150 through a tunnel effect. When no voltage or a low voltage (e.g., a standby voltage or a read voltage) is applied to the gate electrode 170, the first insulating layer 160 may prevent the electric charges captured at the interface of the ferroelectric layer 140 from being leaked through the gate electrode 170. The first insulating layer 160 may be referred to as a tunnel barrier layer.

The first insulating layer 160, with the charge trap layer 150, may contribute to memory window expansion. For example, capacitance occurring between the gate electrode 170 and the ferroelectric layer 140 may be reduced by the first insulating layer 160, and thus, a memory window may expand. The thickness of the first insulating layer 160 may be about 1 nm or more, and/or about 5 nm or less, and/or about 3 nm or less. For example, the thickness of the first insulating layer 160 may be within an inclusive range of 1 nm to 5 nm and/or 1 nm to 3 nm; however, this is an example, but the disclosure is not limited thereto.

The second insulating layer 130 disposed between the channel layer 111 and the ferroelectric layer 140 may include various insulating materials. The second insulating layer 130 may include an oxide of the material included in the channel layer 111. For example, when the channel layer 111 includes Si, the second insulating layer 130 may include SiO₂. When the channel layer 111 includes Ge, the second insulating layer 130 may include GeO₂. When the channel layer 111 includes SiGe, the second insulating layer 130 may include SiGeO₄. The second insulating layer 130 may be formed as a portion of a semiconductor material included in the channel layer 111 is naturally oxidized as above. Alternatively, an additional deposition process and/or the like may be further performed depending on the thickness required for the second insulating layer 130. The second insulating layer 130 may include a plurality of layers.

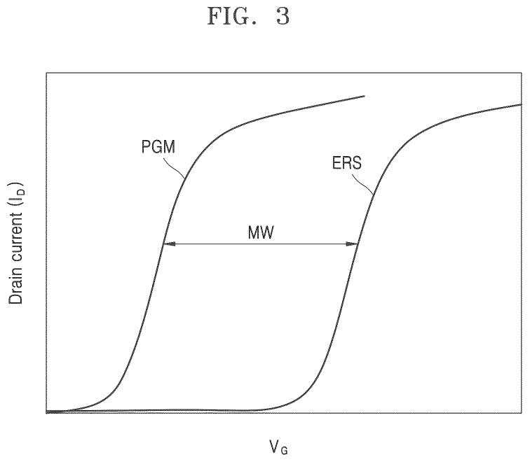

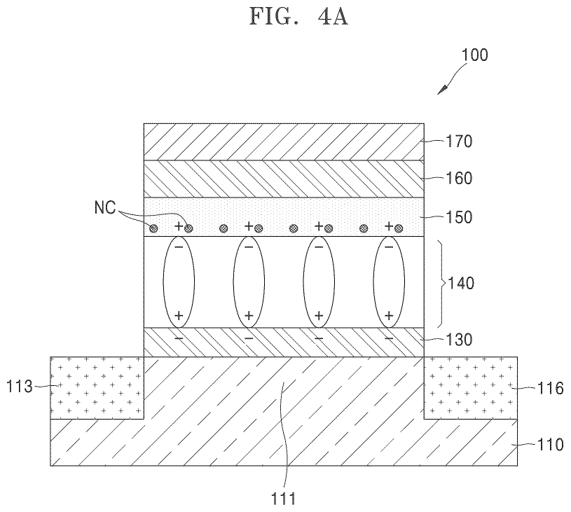

FIG. 3 is a graph conceptually describing a memory window indicated by a semiconductor device according to at least one embodiment.

Two graphs indicated by PGM and ERS show drain currents to a gate voltage VG in a program state (PGM) and an erase state (ERS). A memory window MW is a difference between two different threshold voltages of the semiconductor device 100. As the memory window MW increases, the operation reliability of the semiconductor device 100 may be improved. For example, the memory window MW of the semiconductor device 100 may be about 6.5 V or more.

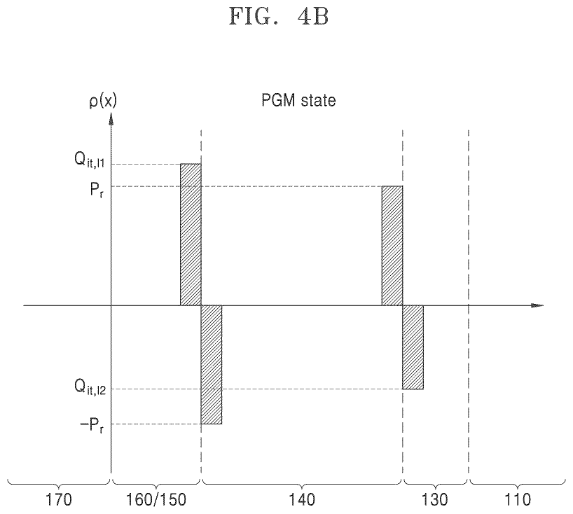

FIG. 4A is a conceptual view illustrating an electric charge distribution in a semiconductor device according to at least one embodiment when the semiconductor device is in a program state. FIG. 4B illustrates an example of an electric charge density in a semiconductor device according to at least one embodiment when the semiconductor device is in the program state.

Referring to FIG. 4A, when the semiconductor device 100 is an NMOS, in the ferroelectric layer 140, positive electric charges may move toward the channel layer 111 and negative electric charges may move toward the gate electrode 170, and the semiconductor device 100 may be in a program state. In the program state, the negative electric charges may be gathered in the second insulating layer 130, and the positive electric charges may be gathered in the charge trap layer 150. In the second insulating layer 130, the negative electric charges may be gathered at the interface with the ferroelectric layer 140, and in the charge trap layer 150, the positive electric charges may be gathered at the interface with the ferroelectric layer 140. In this program state, electrons may easily flow along the channel layer 111, and the threshold voltage of the semiconductor device 100 may be reduced.

In the graph of FIG. 4B, the vertical axis indicates an electric charge density, and the gate electrode 170, the first insulating layer 160, the charge trap layer 150, the ferroelectric layer 140, the second insulating layer 130, and the channel layer 111 in the semiconductor device 100 are located in a horizontal axis direction.

Referring to FIG. 4B, in the charge trap layer 150, an electric charge density Q_{it,I1} of the positive electric charges captured at the interface with the ferroelectric layer 140 may be greater than a polarization value Pᵣ of the ferroelectric layer 140. In the second insulating layer 130, an absolute value of an electric charge density Q_{it,I2} of the negative electric charges captured at the interface with the ferroelectric layer 140 may be less than the absolute value of a polarization value −Pᵣ of the ferroelectric layer 140.

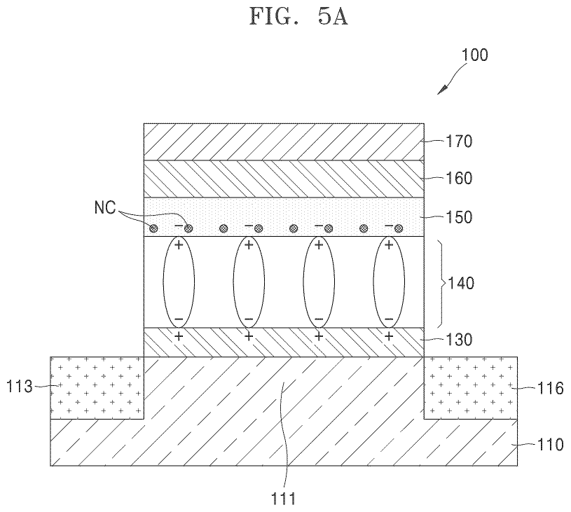

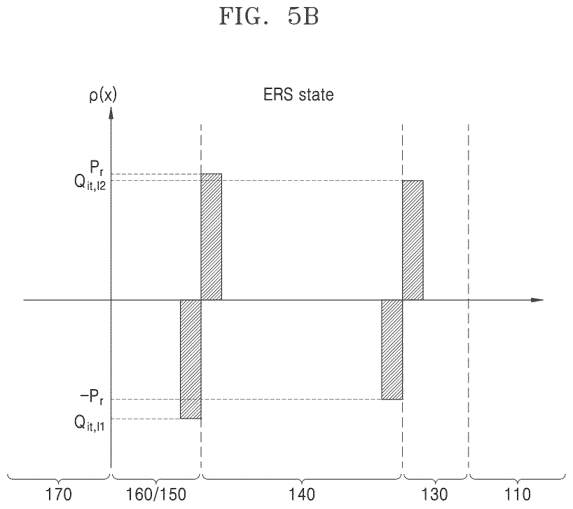

FIG. 5A is a conceptual view illustrating an electric charge distribution in a semiconductor device according to at least one embodiment when the semiconductor device is in an erase state. FIG. 5B illustrates an example of an electric charge density in a semiconductor device according to at least one embodiment when the semiconductor device is in the erase state.

Referring to FIG. 5A, when the semiconductor device 100 is an NMOS, in the ferroelectric layer 140, negative electric charges may move toward the channel layer 111 and positive electric charges may move toward the gate electrode 170, and the semiconductor device 100 may be in an erase state. The program state and the erase state may be selectively switched by applying a positive breakdown voltage or a negative breakdown voltage to the gate electrode 170 of the semiconductor device 100. In the erase state, the positive electric charges may be gathered in the second insulating layer 130, and the negative electric charges may be gathered in the charge trap layer 150. In the second insulating layer 130, the positive electric charges may be gathered at the interface with the ferroelectric layer 140, and furthermore, in the charge trap layer 150, the negative electric charges may be gathered at the interface with the ferroelectric layer 140. In this erase state, electrons may be difficult to flow along the channel layer 111, and the threshold voltage of the semiconductor device 100 may be increased.

Referring to FIG. 5B, in the charge trap layer 150, the absolute value of an electric charge density Q_{it,I1} of the negative electric charges captured at the interface with the ferroelectric layer 140 may be greater than the absolute value of the polarization value −Pᵣ of the ferroelectric layer 140. In the second insulating layer 130, the electric charge density Q_{it,I2} of the positive electric charges captured at the interface with the ferroelectric layer 140 may be less than the polarization value Pᵣ of the ferroelectric layer 140.

In the descriptions of FIGS. 4A to 5B, although a case of the semiconductor device 100 being an NMOS is described, the same principle may be applied to a case of the semiconductor device 100 being a PMOS. For example, in the case of the semiconductor device 100 being a PMOS, the polarizations of the electric charges described in FIGS. 4A to 5B may be opposite to each other.

As the semiconductor device 100 according to at least one embodiment includes the charge trap layer 150 that is designed to increase an electric charge trap amount, the memory window of the semiconductor device 100 may be increased.

The memory window of the semiconductor device 100 may be expressed by the following Equation 1.

$$MW = \frac{( Δ P - Δ {Q}_{it , I 2} )}{{C}_{Ferro}} + \frac{( Δ {Q}_{it , I 1} - Δ {Q}_{it , I 2} )}{{C}_{I 1}} \qquad [ Equation 1 ]$$

In Equation 1, ΔP denotes a polarization amount of the ferroelectric layer 140, ΔQ_{it,I2} denotes an amount of electric charges trapped at the interface between the ferroelectric layer 140 and the second insulating layer 130, ΔQ_{it,I1} denotes an amount of electric charges trapped at the interface between the ferroelectric layer 140 and the charge trap layer 150, C_{Ferro} denotes the capacitance of the ferroelectric layer 140, and C_{I1} denotes the capacitance by the layers between the gate electrode 170 and the ferroelectric layer 140.

As described above, the semiconductor device 100 according to at least one embodiment employs the charge trap layer 150 including the nano-crystals NC to increase ΔQ_{it,I1}. The nano-crystals NC are confined to a certain area adjacent to the ferroelectric layer 140 in the charge trap layer 150 and form a deep trap site. Accordingly, the semiconductor device 100 may have a large memory window.

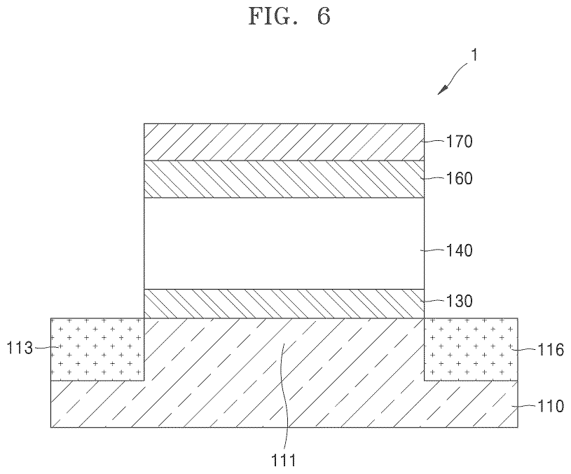

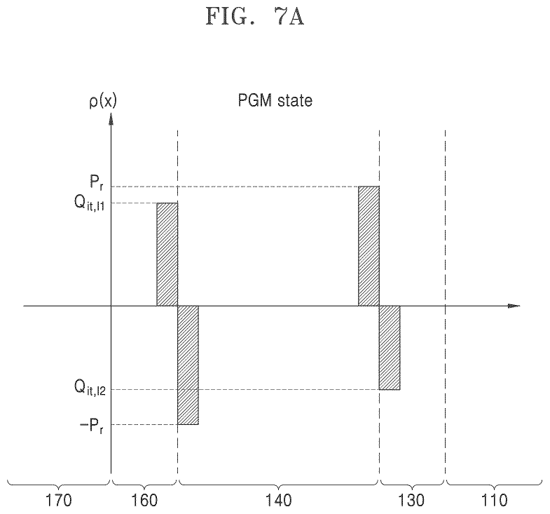

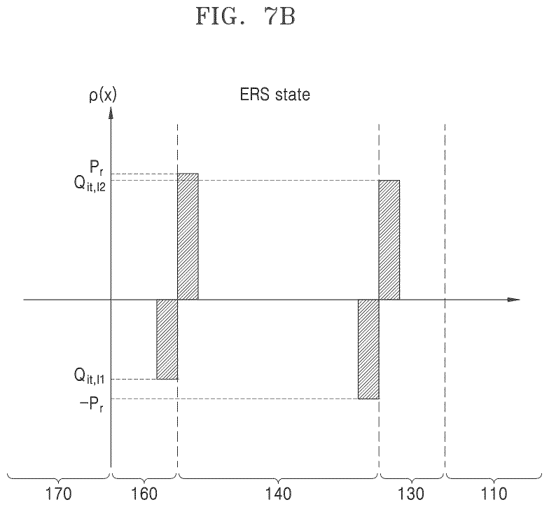

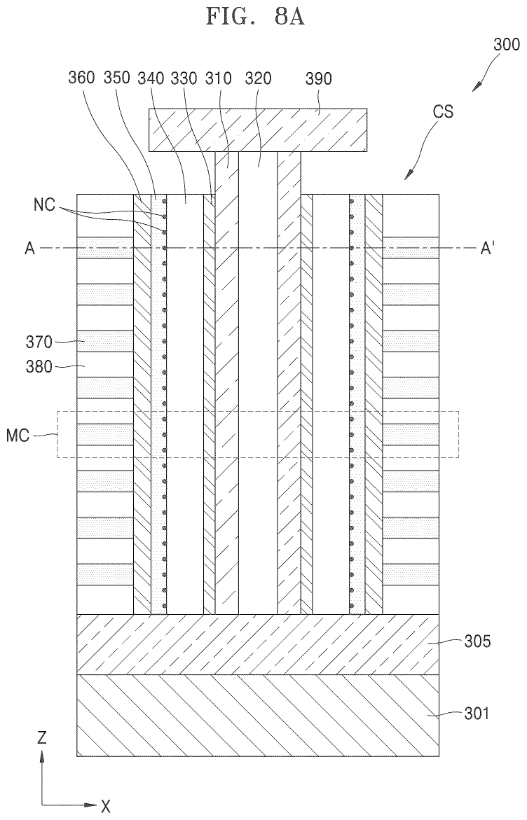

FIG. 6 is a cross-sectional view of a schematic structure of a semiconductor device 1 according to a comparative example. FIGS. 7A and 7B illustrate examples of an electric charge density in the semiconductor device 1 according to a comparative example when the semiconductor device is in a program state and an erase state.

The semiconductor device 1 according to a comparative example differs from the semiconductor device 100 of FIG. 1 in that only the first insulating layer 160 is provided between the ferroelectric layer 140 and the gate electrode 170 and the charge trap layer 150 in FIG. 1 is not included therebetween.

Referring to FIG. 7A, in a program state, in the first insulating layer 160, the electric charge density Q_{it,I1} of the positive electric charges captured at the interface with the ferroelectric layer 140 is less than the polarization value Pᵣ of the ferroelectric layer 140. Comparing FIG. 7A with FIG. 4B, Q_{it,I1} in FIG. 7A may have a value less than the electric charge density Q_{it,I1} of the positive electric charges captured at the interface with the ferroelectric layer 140 in the charge trap layer 150 of FIG. 4B.

Referring to FIG. 7B, in an erase state, in the first insulating layer 160, the absolute value of the electric charge density, Q_{it,I1} of the negative electric charges captured at the interface with the ferroelectric layer 140 may be less than the absolute value of the polarization value −Pᵣ of the ferroelectric layer 140. Comparing FIG. 7B with FIG. 5B, the absolute value of Q_{it,I1} in FIG. 7B may have a value less than the absolute value of the electric charge density Q_{it,I1} of the negative electric charges captured at the interface with the ferroelectric layer 140 in the charge trap layer 150 in FIG. 5B.

When Equation 1 with respect to the memory window is applied to the semiconductor device 1 according to a comparative example, this time, ΔQ_{it,I1} indicates an amount of electric charges trapped at the interface between the ferroelectric layer 140 and the first insulating layer 160. Accordingly, the semiconductor device 1 according to a comparative example may be analyzed to have a smaller memory window than that of the semiconductor device 100 according to at least one embodiment.

In other words, in the semiconductor device 100 according to at least one embodiment, as the charge trap layer 150 including the nano-crystals NC, in addition to the first insulating layer 160, is further provided between the gate electrode 170 and the ferroelectric layer 140, the memory window may be further increased.

The semiconductor device 100 described above may be applied to various electronic devices, for example, as individual memory cell in a memory device. The memory device may have a three-dimensional structure, a gate all around (GAA) structure, a vertical structure, and/or the like, for example, a vertical NAND (VNAND) structure.

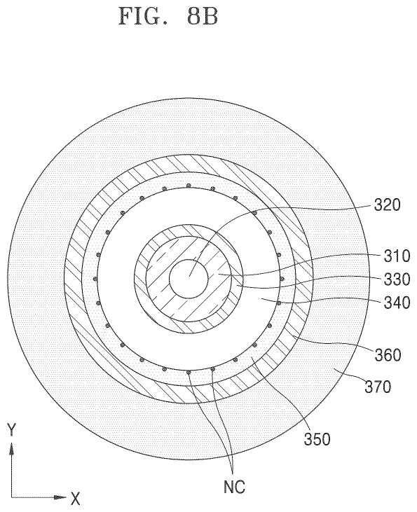

FIG. 8A is a cross-sectional view showing a schematic structure of a memory device 300 according to at least one embodiment, and FIG. 8B is a cross-sectional view of the memory device 300 of FIG. 8A taken along line A-A′.

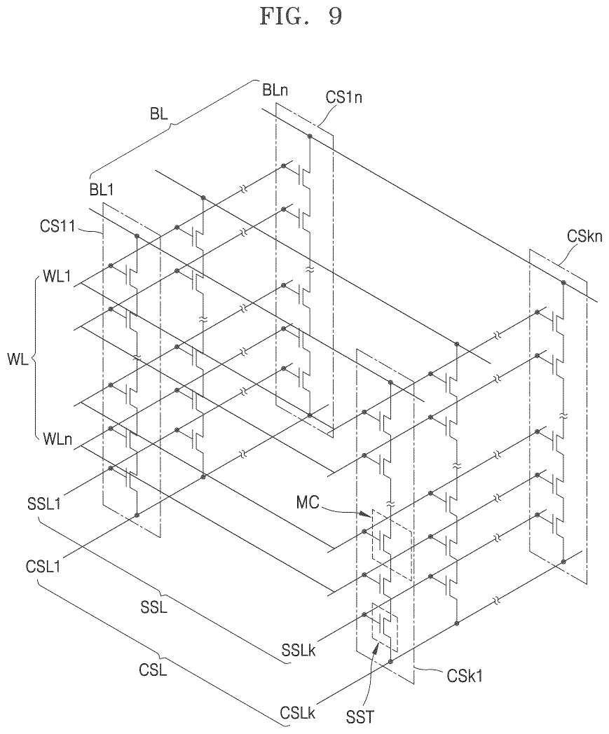

Referring to FIG. 8A, the memory device 300 may include a substrate 301 and a cell string CS formed on the substrate 301. Although one cell string CS is illustrated in the drawing, this is an example, and the memory device 300 may include a plurality of cell strings CS. For example, the cell strings CS may be arranged two-dimensionally in two directions perpendicular to a direction (Z direction) away from the substrate 301. The cell strings CS may be arranged in a matrix form of k*n, as illustrated in a circuit diagram of FIG. 9 to be described below, and may be referred to as CSij (1≤i≤k, 1≤j≤n) according to the respective row and column positions.

The substrate 301 may be a semiconductor substrate. The substrate 301 may include a silicon material doped with first-type impurities. For example, the substrate 301 may include a silicon material doped with p-type impurities. For example, the substrate 301 may be a p-type well (e.g., a pocket p well). However, the disclosure is not limited thereto, and the substrate 301 may include various semiconductor materials.

A common source region 305 is provided on the substrate 301. The common source region 305 may be a different type from a semiconductor material included in the substrate 301, for example, an n-type. The common source region 305 may be connected to, for example, a common source line CSL that is indicated in a circuit diagram of FIG. 9.

The cell string CS may have a circuit cross-section, as illustrated in the cross-sectional view in FIG. 8B. In other words, the cell string CS may have a cylindrical shape with a central axis parallel to the Z direction. However, this is an example, and the cell string CS may have other shapes, and, for example, may be deformed into the shape of an oval column or a polygonal column.

A plurality of gate electrodes 370 may be spaced apart from each other in the axis direction of the cell string CS, for example, in the Z direction, and a spacer 380 including an insulating material may be disposed between the gate electrodes 370.

The gate electrodes 370 and the spacer 380 may have a cylinder shell shape with connected inner surfaces, and a first insulating layer 360 may be conformally formed on the inner surface. Next, a charge trap layer 350 may be conformally formed on the first insulating layer 360. A ferroelectric layer 340 is conformally formed on the charge trap layer 350, and then, a second insulating layer 330 and a channel layer 310 may be conformally formed. The charge trap layer 350 is substantially the same as the charge trap layer 150 described in FIGS. 1 and 2A, and may include the nano-crystals NC arranged within a certain distance from an interface with the ferroelectric layer 340.

The center portion of the cell string CS may be filled with an insulating layer 320 that is cylindrical. However, this is an example, and the insulating layer 320 may be omitted or formed in a cylinder shell shape.

The channel layer 310, the second insulating layer 330, the ferroelectric layer 340, the charge trap layer 350, the first insulating layer 360, and the gate electrodes 370 may include the materials of the channel layer 111, the second insulating layer 130, the ferroelectric layer 140, the charge trap layer 150, the first insulating layer 160, and the gate electrode 170, which are described in FIG. 1. As such, repeat descriptions thereof have been omitted.

One end of the channel layer 310, that is, an area of the channel layer 310 located in the lowermost end of the cell string CS may be in contact with the common source region 305.

A drain 390 may be provided on the cell string CS. The drain 390 may include, for example, a silicon material doped in an n type. The other end of the channel layer 310, that is, an area of the channel layer 310 located in the uppermost end of the cell string CS may be in contact with the drain 390. The drain 390 may be connected to a bit line through contact plugs.

An area of one of the gate electrodes 370, and the first insulating layer 360, the ferroelectric layer 340, the second insulating layer 330, and the channel layer 310, which are in an area facing the gate electrode 370, constitute a memory cell MC.

As the memory cells MC are continuously arranged in the vertical direction (Z direction), the cell string CS is formed. The common source region 305 and the drain 390, which are connected to the opposite ends of the cell string CS, may be respectively connected to the common source line CSL and a bit line BL, which are illustrated in the circuit diagram of FIG. 9. The gate electrodes 370 are connected to a word line WL. By applying a voltage to the word line WL, the common source line CSL, and the bit line BL, program, read, and erase processes may be performed on the memory cells MC.

As described above, the ferroelectric layer 340 is a material in which a polarization value (polarization) remains semi-permanently even when a certain voltage is applied thereto and reduced back to 0 V, and the polarity (direction) of the remnant polarization may depend on the polarity (direction) of an externally applied voltage. The area of the ferroelectric layer 340 corresponding to each memory cell MC may have remnant polarization corresponding to an electric field formed in the ferroelectric layer 340 by a voltage applied to the gate electrodes 370. A conductance difference may be generated in the area of the channel layer 310 corresponding to the memory cell MC, by the polarization direction of the ferroelectric layer 340, through which information may be written or confirmed.

Furthermore, as the memory device 300 according to at least one embodiment includes the charge trap layer 350 having a certain concentration gradient in order to increase the memory window, the reliability of a memory operation may be improved.

FIG. 9 is an equivalent circuit of a memory device according to at least one embodiment. Referring to FIG. 9, the memory device may include a plurality of memory cell strings CS11 to CSkn. The memory cell strings CS11 to CSkn are arranged two-dimensionally in a row direction and a column direction and may form rows and columns. Each cell string CSij (1≤i≤k and 1≤j≤n) may be connected to the bit line BL, a string selection line SSL, the word line WL, and the common source line CSL.

The cell string CSij may include the memory cells MC and a string selection transistor SST. The memory cells MC and the string selection transistor SST of each cell string CSij may be stacked in a height direction.

The rows of the cell strings CSij are respectively connected to different string selection lines SSL1 to SSLk. For example, the string selection transistors SST of the cell strings CS11 to CS1n are commonly connected to the string selection line SSL1. The string selection transistors SST of the cell strings CSk1 to CSkn are commonly connected to the string selection line SSLk.

The columns of the cell strings CSij are respectively connected to different bit lines BL1 to BLn. For example, the memory cells MC and the string selection transistors SST of the cell strings CS11 to CSk1 may be commonly connected to the bit line BL1, and the memory cells MC and the string selection transistors SST of the cell strings CS1n to CSkn may be commonly connected to the bit line BL (BLn).

The rows of the cell strings CSij may be respectively connected to different common source lines CSL1 to CSLk. For example, the string selection transistors SST of the cell strings CS11 to CS1n may be commonly connected to the common source line CSL1, and the string selection transistors SST of the cell strings CSk1 to CSkn may be commonly connected to the common source line CSLk.

The string selection transistors SST or the memory cells MC located at the same height from the substrate 301 of FIG. 8A may be commonly connected to one of word lines WL1 to WLm, and the memory cells MC located at different heights may be respectively connected to the word lines WL1 to WLm different from each other.

In the structure, write and read operations may be performed in units of rows of the memory cell strings CS11 to CSkn. For example, the memory cell strings CS11 to CSkn may be selected in units of one row by the common source line CSLS and the string selection lines SSL. The write and read operations may be performed in units of pages on the selected row of the memory cell strings CS11 to CSkn. For example, the page may be one row of the memory cells MC connected to one word line WL. In the selected row of the memory cell strings CS11 to CSkn, the memory cells MC may be selected in units of pages by the word lines WL. Each of the memory cells MC may be the same as (and/or substantially similar to) the memory cells MC of FIG. 8A. may include the semiconductor device 100, and/or may include a semiconductor device deformed therefrom.

The illustrated circuit structure is an example. For example, the number of the rows of the cell strings CSij (1≤i≤k and 1≤j≤n) may be increased or decreased. As the number of rows of the cell string CS is changed, the number of string selection lines connected to the rows of the cell string CS and the number of the cell strings CS connected to one bit line BL may be changed. As the number of rows of the cell strings CS is changed, the number of common source lines connected to the rows of the cell strings CS may also be changed.

The number of the columns of the cell strings CSij may be increased or decreased. As the number of the columns of the cell strings CSij is changed, the number of the bit lines BL connected to the columns of the cell strings CSij and the number of the cell strings CSij connected to one string selection line may be also be changed.

The heights of the cell strings CSij may be increased or decreased. For example, the number of the memory cells MC stacked on each of the cell strings CSij may be increased or decreased. As the number of the memory cells MC stacked on each of the cell strings CSij is changed, the number of the word lines WL may also be changed. For example, the string selection transistor provided to each of the cell strings CSij may be increased. As the number of the string selection transistors provided to each of the cell strings CSij is changed, the number of the string selection lines or the common source lines may be changed. As the number of the string selection transistors is increased, the string selection transistors may be stacked in the same form as the memory cells MC.

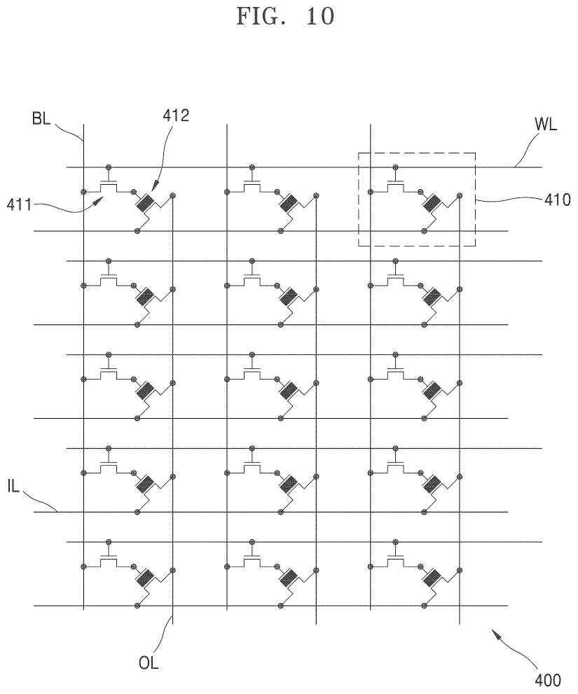

FIG. 10 is a schematic circuit diagram of a neural network device 400 according to at least one embodiment. Referring to FIG. 10, the neural network device 400 according to at least one embodiment may include an array of a plurality of synapse devices 410 that are arranged two-dimensionally. Each of the synapse devices 410 may include an access transistor 411 and a ferroelectric field effect transistor 412. The ferroelectric field effect transistor 412 may be the semiconductor device 100 described in FIGS. 1 to 5B, and/or a semiconductor device deformed therefrom. The access transistor 411 may function as a selection device to turn the synapse devices 410 on/off.

The neural network device 400 may also include a plurality of word lines WL, a plurality of bit lines BL, a plurality of input lines IL, and a plurality of output lines OL. In the access transistor 411, a gate may be electrically connected to any one word line of the word lines WL, a source may be electrically connected to any one bit line of the bit lines BL, and a drain may be electrically connected to a gate of the ferroelectric field effect transistor 412. Furthermore, in the ferroelectric field effect transistor 412, a source may be electrically connected to any one input line of the input lines IL, and a drain may be electrically connected to any one output line of the output lines OL.

In a training operation of the neural network device 400, the access transistor 411 is individually turned on through an individual word line WL, and a program pulse may be applied to a gate of the ferroelectric field effect transistor 412 through the bit line BL. A signal of training data may be applied through the input lines IL. A weight may be stored in each of the ferroelectric field effect transistor 412 through the process.

During the inference operation of the neural network device 400, all the access transistors 411 are turned on through all the word lines WL, and a read voltage Vread may be applied through the bit line BL. Then, the sum of currents from the synapse devices 410 connected in parallel to the output lines OL may flow in each of the output lines OL. As an output circuit is connected to the output lines OL, a current flowing in each of the output lines OL may be converted into a digital signal.

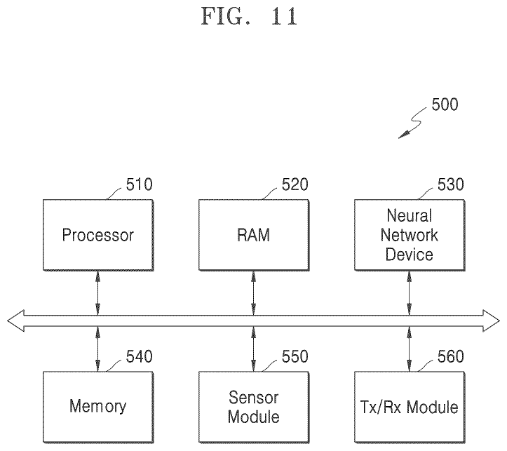

FIG. 11 is a schematic block diagram of an electronic device 500 including a neural network device according to at least one embodiment. Referring to FIG. 11, the electronic device 500 may extract valid information by analyzing input data in real time based on a neural network and make situational determination based on the extracted information, or may control components of a device on which the electronic device 500 is mounted. For example, the electronic device 500 may be applied to robot devices, such as drones, advanced drivers assistance systems (ADAS), and/or the like, smart TVs, smartphones, medical devices, mobile devices, image display devices, measuring devices, IoT devices, and/or the like, and may be additionally mounted at least one of various types of devices.

The electronic device 500 may include a processor 510, random access memory (RAM) 520, a neural network device 530, a memory 540, a sensor module 550, and a communication module 560. The electronic device 500 may further include an input/output module, a security module, a power control device, and/or the like. Some of hardware components of the electronic device 500 may be mounted on at least one semiconductor chip.

The processor 510 controls the overall operation of the electronic device 500. The processor 510 may include one processor core (single core) or a plurality of processor cores (multi-core). The processor 510 may process or execute programs and/or data stored in the memory 540. In some embodiments, the processor 510 may control functions of the neural network device 530 by executing programs stored in the memory 540. The processor 510 may be implemented by a central processing unit (CPU), a graphics processing unit (GPU), an application processor (AP), and/or the like.

The RAM 520 may temporarily store programs, data, or instructions. For example, the programs and/or data stored in the memory 540 may be temporarily stored in the RAM 520 under the control of the processor 510 or according to booting code. The RAM 520 may be implemented by memory, such as dynamic RAM (DRAM), static RAM (SRAM), and/or the like.

The neural network device 530 may be configured to perform an operation of a neural network based on the received input data, and generate an information signal based on a result of the performance of the operation. The neural network may include a convolution neural network (CNN), a recurrent neural network (RNN), a feedforward neural network (FNN), a long short-term memory (LSTM), a stacked neural network (SNN), a state-space dynamic neural network (SSDNN), a deep belief network (DBN), a restricted Boltzmann machine (RBM), and/or the like, but the disclosure is not limited thereto. The neural network device 530 may be a neural network dedicated hardware accelerator itself or a device including the same. The neural network device 530 may perform not only an operation of a neural network, but also a read or write operation. The neural network device 530 may correspond to a neural network device 400 according to at least one embodiment which is illustrated in FIG. 10.

The information signal may include one of various types of recognition signals, such as a voice recognition signal, an object recognition signal, an image recognition signal, a biometric information recognition signal, and/or the like. For example, the neural network device 530 may receive frame data included in a video stream, as input data, and generate, from the frame data, a recognition signal for an object included in the image represented by the frame data. However, the disclosure is not limited thereto, and based on the type or function of a device on which the electronic device 500 is mounted, the neural network device 530 may receive various types of input data and generate a recognition signal according to the input data.

The neural network device 530 may be configured to perform, for example, a machine learning model, such as linear regression, logistic regression, statistical clustering, Bayesian classification, decision trees, principal component analysis, and/or an expert system, and/or a machine learning model, such as ensemble technique, such as random forest, and/or the like. These machine learning models may be used to provide various services, such as image classification services, user authentication services based on biometric information or biological data, ADAS, voice assistant services, automatic speech recognition (ASR) services, and/or the like.

The memory 540, which is a place for storing data, may store operating system (OS), various programs, and various pieces of data. In at least one embodiment, the memory 540 may store intermediate results generated in operation processes of the neural network device 530.

The memory 540 may include DRAM, but the disclosure is not limited thereto. The memory 540 may include at least one of volatile memory or non-volatile memory. The non-volatile memory may include read only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), and/or the like. The volatile memory may include dynamic RAM (DRAM), static RAM (SRAM), synchronous DRAM (SDRAM), phase-change RAM (PRAM), magnetic RAM (MRAM), resistive RAM (RRAM), ferroelectric RAM (FeRAM), and/or the like. In at least one embodiment, the memory 540 may include at least one of a hard disk drive (HDD), a solid-state drive (SSD), compact flash (CFs), secure digital (SD), micro secure digital (Micro-SD), mini secure digital (Mini-SD), or Memory Stick.

The sensor module 550 may collect information around a device on which the electronic device 500 is mounted. The sensor module 550 may sense or receive a signal from the outside of the electronic device 500 (e.g., an image signal, a voice signal, a magnetic signal, a biological signal, a touch signal, and/or the like), and convert the sensed or received signal into data. To this end, the sensor module 550 may include at least one of various types of sensing devices, such as a microphone, an imaging device, an image sensor, a light detection and ranging (LIDAR) sensor, an ultrasound sensor, an infrared sensor, a biosensor, a touch sensor, and/or the like.

The sensor module 550 may provide converted data, as input data, to the neural network device 530. For example, the sensor module 550 may include an image sensor, and may generate a video stream by photographing the external environment of the electronic device 500, and provide successive data frames of the video stream, as input data, to the neural network device 530. However, the disclosure is not limited thereto, and the sensor module 550 may provide various types of data to the neural network device 530.

The communication module 560 may include various wired or wireless interfaces for communication with an external device. For example, the communication module 560 may include a communication interface capable of accessing a mobile cellular network and/or the like, such as a wired local area network (LAN), a wireless local area network (WLAN) such as wireless fidelity (Wi-Fi), a wireless personal area network (WPAN) such as Bluetooth, a wireless universal serial bus (USB), Zigbee, near field communication (NFC), radio-frequency identification (RFID), power line communication (PLC), or 3rd generation (3G), 4th generation (4G), long term evolution (LTE), and/or the like.

The semiconductor device described above may operate as a field effect transistor with an increased memory window.

The semiconductor device described above may have improved operation reliability and may be used as a memory cell of a memory device.

It should be understood that the semiconductor device described above and an electronic device including the same described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer comprising a semiconductor material;
a gate electrode on the channel layer;
a ferroelectric layer between the channel layer and the gate electrode, the ferroelectric layer comprising a ferroelectric material;
a first insulating layer between the ferroelectric layer and the gate electrode;
a charge trap layer between the ferroelectric layer and the first insulating layer, the charge trap layer comprising a matrix material and a plurality of nano-crystals embedded in the matrix material; and
a second insulating layer between the channel layer and the ferroelectric layer,
wherein, in the charge trap layer, a center of an overall arrangement of the plurality of nano-crystals is in an area closer to the ferroelectric layer than to the first insulating layer.

2. The semiconductor device of claim 1, wherein
the plurality of nano-crystals comprise an element included in the matrix material.

3. The semiconductor device of claim 1, wherein the center of the overall arrangement of the plurality of nano-crystals is at a distance of 2 nm or less from an interface between the ferroelectric layer and the charge trap layer.

4. The semiconductor device of claim 1, wherein at least two of the plurality of nano-crystals are spaced apart from each other.

5. The semiconductor device of claim 1, wherein at least a majority of the plurality of nano-crystals are located within 70% or less of a thickness of the charge trap layer from an interface between the ferroelectric layer and the charge trap layer.

6. The semiconductor device of claim 1, wherein the plurality of nano-crystals are arranged such as the plurality of nano-crystals are not entirely connected to each other and do not to form a layer.

7. The semiconductor device of claim 1, wherein, a volume ratio of the plurality of nano-crystals in an area at a first distance from the first surface is 50% or less, and
the first distance is a distance between one end of a nano-crystal, of the plurality of nano-crystals, located farthest from an interface between the ferroelectric layer and the charge trap layer and the interface.

8. The semiconductor device of claim 1, wherein the charge trap layer comprises at least one of AlN, GaN, GeN, SiN, CN, InN, YN, ScN, or ZrN.

9. The semiconductor device of claim 1, wherein the matrix material comprises SiN, and the plurality of nano-crystals comprise Si.

10. The semiconductor device of claim 1, wherein the matrix material comprises GeN, and the plurality of nano-crystals comprise Ge.

11. The semiconductor device of claim 1, wherein the second insulating layer comprises an oxide of a material included in the channel layer.

12. The semiconductor device of claim 1, wherein the ferroelectric material included in the ferroelectric layer comprises a hafnium oxide-based material.

13. The semiconductor device of claim 12, wherein the hafnium oxide-based material includes a dopant and the dopant comprises at least one of Zr, La, Al, Si, Y, B, or Sc.

14. The semiconductor device of claim 1, wherein the channel layer comprises at least one of Si, Ge, SiGe, MoS₂, WSe₂, graphene, indium gallium zinc oxide (IGZO), tungsten doped indium oxide (IWO), or ZnSnO.

15. An electronic device comprising:
a semiconductor substrate; and
a plurality of memory cells stacked on the semiconductor substrate,
wherein each of the plurality of memory cells comprises
a channel layer comprising a semiconductor material,
a plurality of gate electrodes spaced apart from each other in a first direction,
a ferroelectric layer between the channel layer and the plurality of gate electrodes, the ferroelectric layer comprising a ferroelectric material,
a first insulating layer between the ferroelectric layer and the plurality of gate electrodes,
a charge trap layer between the ferroelectric layer and the first insulating layer, the charge trap layer comprising a matrix material and a plurality of nano-crystals embedded in the matrix material, and
a second insulating layer disposed between the channel layer and the ferroelectric layer,
wherein, the charge trap layer, a center of an overall arrangement of the plurality of nano-crystals is in an area closer to the ferroelectric layer than to the first insulating layer, and
wherein the first direction is perpendicular to a stack direction of the plurality of memory cells.

16. The electronic device of claim 15, wherein the plurality of nano-crystals comprise an element included in the matrix material.

17. The electronic device of claim 15, wherein the center of the overall arrangement of the plurality of nano-crystals is at a distance of 2 nm or less from an interface between the ferroelectric layer and the charge trap layer.

18. The electronic device of claim 15, further comprising:
a plurality of spacers, including an insulating material, between the plurality of gate electrodes adjacent to each other.

19. The electronic device of claim 18, wherein the plurality of gate electrodes and the plurality of spacers have a cylinder shell shape with connected inner surfaces.

20. An electronic device comprising:
an array comprising a plurality of synapse devices that are two-dimensionally arranged,
wherein each of the plurality of synapse devices comprises an access transistor and a ferroelectric field effect transistor,
wherein the ferroelectric field effect transistor comprises
a channel layer comprising a semiconductor material,
a plurality of gate electrodes spaced apart from each other in a first direction,
a ferroelectric layer between the channel layer and the plurality of gate electrodes, the ferroelectric layer comprising a ferroelectric material,
a first insulating layer between the ferroelectric layer and the plurality of gate electrodes,
a charge trap layer between the ferroelectric layer and the first insulating layer, the charge trap layer comprising a matrix material and a plurality of nano-crystals embedded in the matrix material, and
a second insulating layer between the channel layer and the ferroelectric layer, and
wherein, in the charge trap layer, a center of an overall arrangement of the plurality of nano-crystals is in an area closer to the ferroelectric layer than to the first insulating layer.
